(19) United States
(12) Patent Application Publication
(10) Pub. No.: US 2006/0164104 A1
(43) Pub. Date: Jul. 27, 2006

(54) Measuring apparatus

(76) Inventors: Mitsuo Tada, Tokyo (JP); Yasunari Suto, Tokyo (JP)

Correspondence Address: WENDEROTH, LIND & PONACK, L.L.P., 2033 K STREET N. W., SUITE 800, WASHINGTON, DC, 20006-1021, US

(21) Appl. No.: 10/559,476

(22) PCT Filed: Jun. 10, 2004
(86) PCT No.: PCT/JP04/08467

§ 371 Date: Apr. 3, 2006

(30) Foreign Application Priority Data
Jun. 13, 2003 (JP) 2003-169983

(51) Int. Cl. G01R 27/04

(52) U.S. Cl. 324/646

(57) ABSTRACT

The present invention relates to a measuring apparatus for measuring a thickness or the like of a thin film formed on a surface of a substrate such as a semiconductor wafer. The measuring apparatus includes a microwave emission device (40) for emitting a microwave to a substance, a microwave generator (45) for supplying the microwave to the microwave emission device (40), a detector (47) for detecting an amplitude or a phase of the microwave which has been reflected from or passed through the substance, and an analyzer (48) for analyzing a structure of the substance based on the amplitude or the phase of the microwave which has been detected by the detector (47).

### TECHNICAL FIELD

The present invention relates to a measuring apparatus for measuring a thickness or the like of a substance, and more particularly to a measuring apparatus for measuring a thickness or the like of a thin film formed on a surface of a substrate such as a semiconductor wafer.

### BACKGROUND ART

As semiconductor devices have become more highly integrated in recent years, circuit interconnects have been required to be finer, and the number of layers in multilayer interconnects has been increased. Under such a tendency, there has been a demand for planarizing a surface of a substrate such as a semiconductor wafer. Specifically, as the circuit interconnects become finer, a wave length of a light used in a photolithography becomes shorter. In case of using such a light having a short wave length, step heights that can be allowed in focus regions on the surface of the substrate become smaller. Thus, a highly flat surface is required for the substrate so that the step heights in the focus regions become small. From this viewpoint, it has been customary to remove irregularities formed on the surface of the semiconductor wafer so as to obtain a flat surface by a chemical mechanical polishing (CMP) process. In a chemical mechanical polishing process that is performed by a CMP apparatus, a semiconductor wafer as an object to be polished is brought into sliding contact with a polishing pad while a polishing liquid is supplied onto the polishing pad. The semiconductor wafer is thus polished.

In the above-mentioned chemical mechanical polishing process, it is necessary to stop a polishing process at a predetermined point after the polishing process is performed for a predetermined period of time. For example, there is a case where an insulating layer such as SiO2 is required to remain on metal interconnects such as Cu or Al. Such an insulating layer is referred to as an interlayer dielectric because a layer such as a metal layer is formed on the insulating layer in a subsequent process. In such a case, if the insulating layer is excessively polished, then the metal interconnects underneath the insulating layer may be exposed. Thus, the polishing process should be stopped at a predetermined point so as to allow the insulating layer (interlayer dielectric) to remain on the metal interconnects with a certain thickness.

There is also another case where interconnect grooves having predetermined patterns, which have been formed in advance on a surface of a semiconductor wafer, are filled with Cu (or Cu alloy) and then unnecessary portion of Cu layer remaining on the surface is removed by the chemical mechanical polishing (CMP) process. When the Cu layer is removed by the CMP process, it is required to selectively remove the Cu layer from the semiconductor wafer so that the Cu layer remains only in the interconnect grooves. Specifically, the Cu layer is required to be removed from the surface in such a manner that the insulating layer (non-metal layer) such as SiO2 is exposed at portions other than the interconnect grooves.

In this case, if the polishing process is excessively performed to polish the Cu layer in the interconnect grooves together with the insulating layer, a circuit resistance becomes large, and hence the semiconductor device should be discarded, resulting in a large loss. In contrast thereto, if the polishing process is not sufficiently performed to allow the Cu layer to remain on the insulating layer, the circuit interconnects are not divided from each other, thus causing a short circuit. As a result, the polishing process should be performed again, and hence a fabrication cost is increased. Such a problem occurs not only in case of polishing the Cu layer, but also in case of polishing other kinds of metal layers such as Al layer by the CMP process after forming such a metal layer.

Therefore, it has heretofore been customary to measure a thickness of an insulating layer (insulating film) or a metal layer (metal film) formed on a surface, to be polished, with use of a measuring apparatus having an optical sensor so as to detect an end point of a CMP process. In this kind of measuring apparatus, a laser beam or a white light is emitted from a light source to a semiconductor wafer while a polishing process is performed, and a reflected light from the insulating film or the metal film formed of the semiconductor wafer is measured so as to detect the end point of the polishing process. In another type of measuring apparatus, a visible ray is emitted from a light source to a semiconductor wafer while a polishing process is performed, and a reflected ray from the insulating film or the metal film formed of the semiconductor wafer is analyzed with use of a spectroscope so as to detect the end point of the polishing process.

However, the above-mentioned measuring apparatuses have the following problems: If an obstacle such as a polishing pad exists between the light source and the semiconductor wafer, the laser beam and the visible ray emitted from the light source cannot reach the semiconductor wafer. Therefore, it is necessary to provide a transmitting window such as a through-hole or a transparent window in the polishing pad so that the laser beam and the visible ray can pass therethrough. As a result, the number of fabrication processes of the polishing pad is increased, and hence the fabrication cost of the polishing pad as an expendable component is increased. Further, in the above-mentioned measuring apparatus, the reflected laser beam and the reflected visible ray from the semiconductor wafer are unstable. Therefore, it is difficult to accurately measure a film thickness.

### DISCLOSURE OF INVENTION

The present invention has been made in view of the above drawbacks. It is therefore an object of the present invention to provide a measuring apparatus which can accurately measure a structure, e.g. a thickness, of a substance without providing a transmitting window such as a through-hole in an obstacle.

In order to achieve the above object, according to one aspect of the present invention, there is provided a measuring apparatus comprising: a microwave emission device for emitting a microwave to a substance; a microwave generator for supplying the microwave to the microwave emission device; a detector for detecting an amplitude or a phase of the microwave which has been reflected from or passed through the substance; and an analyzer for analyzing a structure of the substance based on the amplitude or the phase of the microwave which has been detected by the detector.

In a preferred aspect of the present invention, the analyzer calculates at least one of a reflection coefficient, a standing wave ratio, and a surface impedance.

In a preferred aspect of the present invention, the analyzer measures at least one of a thickness, an internal defect, a dielectric constant, an electric conductivity, and a magnetic permeability of the substance.

According to another aspect of the present invention, there is provided a polishing apparatus for polishing a substrate by bringing the substrate into sliding contact with a polishing pad, the polishing apparatus comprising: a polishing table having the polishing pad; a top ring for holding the substrate and pressing the substrate against the polishing pad; and a measuring apparatus for measuring a thickness of a film formed on a surface of the substrate; wherein the measuring apparatus comprises a microwave emission device for emitting a microwave to the film, a microwave generator for supplying the microwave to the microwave emission device, a detector for detecting an amplitude or a phase of the microwave which has been reflected from or passed through the film, and an analyzer for measuring a thickness of the film based on the amplitude or the phase of the microwave which has been detected by the detector.

In a preferred aspect of the present invention, a plurality of the microwave emission devices are provided in the top ring; one of the plurality of the microwave emission devices is disposed at a position corresponding to a central portion of the substrate; and the others of the plurality of the microwave emission devices are disposed apart from the central portion of the substrate in a radial direction of the substrate.

In a preferred aspect of the present invention, the measuring apparatus further comprises at least one of an eddy current sensor, an optical sensor, a frictional force detector for detecting a frictional force between the polishing pad and the substrate, and a torque sensor for detecting a torque of the top ring or the polishing table.

According to another aspect of the present invention, there is provided a CVD apparatus for forming a film on a surface of a substrate, the CVD apparatus comprising: a chamber in which the substrate is disposed; a gas supply for supplying a material gas into the chamber; a heater for heating the substrate; and a measuring apparatus for measuring a thickness of the film formed on the surface of the substrate; wherein the measuring apparatus comprises a microwave emission device for emitting a microwave to the film, a microwave generator for supplying the microwave to the microwave emission device, a detector for detecting an amplitude or a phase of the microwave which has been reflected from or passed through the film, and an analyzer for measuring a thickness of the film based on the amplitude or the phase of the microwave which has been detected by the detector.

According to another aspect of the present invention, there is provided a measuring apparatus comprising: an emission device for emitting a linearly polarized wave or a circularly polarized wave to a substance; at least two receive devices each for receiving a reflected wave from the substance; at least two detectors each for detecting an amplitude and a phase of the reflected wave; and an analyzer for analyzing a change in polarization state of the reflected wave based on the amplitude and the phase which have been detected by the detectors so as to measure a thickness of the substance.

In a preferred aspect of the present invention, the analyzer further measures a dielectric constant, an electric conductivity, a magnetic permeability, and a refractive index of the substance.

In a preferred aspect of the present invention, the substance is a multilayered film.

According to another aspect of the present invention, there is provided a polishing apparatus for polishing a substrate by bringing the substrate into sliding contact with a polishing pad, the polishing apparatus comprising: a polishing table having the polishing pad; a top ring for holding the substrate and pressing the substrate against the polishing pad; and a measuring apparatus for measuring a thickness of a substance formed on a surface of the substrate; wherein the measuring apparatus comprises an emission device for emitting a linearly polarized wave or a circularly polarized wave to the substance, at least two receive devices each for receiving a reflected wave from the substance, at least two detectors each for detecting an amplitude and a phase of the reflected wave, and an analyzer for analyzing a change in polarization state of the reflected wave based on the amplitude and the phase which have been detected by the detectors so as to measure a thickness of the substance.

In a preferred aspect of the present invention, the emission device is disposed in the polishing table.

In a preferred aspect of the present invention, the substance is a multilayered film.

According to the present invention, even if an obstacle (e.g., a polishing pad) exists between the substance as an object to be measured and the microwave emission device, the microwave passes (penetrates) through the obstacle to reach the substance (e.g., a substrate). Therefore, it is not necessary to provide a transmitting window such as a through-hole in the obstacle. As a result, a process for providing such a transmitting window is not required, and hence the fabrication cost can be reduced. Further, according to the present invention, a thickness or the like of the substance can be measured accurately without being affected by a polishing liquid or the like.

### BRIEF DESCRIPTION OF DRAWINGS

FIG. 1A is a view illustrating a principle of a measuring apparatus according to the present invention;

FIG. 1B is a graph illustrating a relationship between an amplitude of a reflected wave and a thickness of a substance;

FIG. 2 is a cross-sectional view showing a polishing apparatus incorporating a measuring apparatus according to a first embodiment of the present invention;

FIG. 3 is a schematic view showing the measuring apparatus according to the first embodiment of the present invention;

FIG. 4A is a schematic plan view showing the polishing apparatus shown in FIG. 2;

FIG. 4B is a schematic view showing a surface, to be polished, of a semiconductor wafer;

FIG. 5A is a graph illustrating the manner in which measured values of film thickness at respective zones of the surface of the semiconductor wafer are changed with time;

FIG. 5B is a view illustrating a convergence range of the measured values of the film thickness;

FIG. 6 is a graph showing the manner in which the film thickness changes with time;

FIG. 7A is a cross-sectional view showing another example of the polishing apparatus incorporating the measuring apparatus according to the first embodiment of the present invention;

FIG. 7B is an enlarged cross-sectional view showing a top ring shown in FIG. 7A;

FIG. 8 is a cross-sectional view showing an electrolytic polishing apparatus incorporating the measuring apparatus according to the first embodiment of the present invention;

FIG. 9 is a cross-sectional view showing a dry etching apparatus incorporating the measuring apparatus according to the first embodiment of the present invention;

FIG. 10 is a cross-sectional view showing a plating apparatus incorporating the measuring apparatus according to the first embodiment of the present invention;

FIG. 11 is across-sectional view showing a CVD apparatus incorporating the measuring apparatus according to the first embodiment of the present invention;

FIG. 12 is a cross-sectional view showing a PVD apparatus incorporating the measuring apparatus according to the first embodiment of the present invention;

FIG. 13 is a view illustrating a principle of ellipsometry; and

FIG. 14 is a schematic view showing a polishing apparatus incorporating a measuring apparatus according to a second embodiment of the present invention.

### BEST MODE FOR CARRYING OUT THE INVENTION

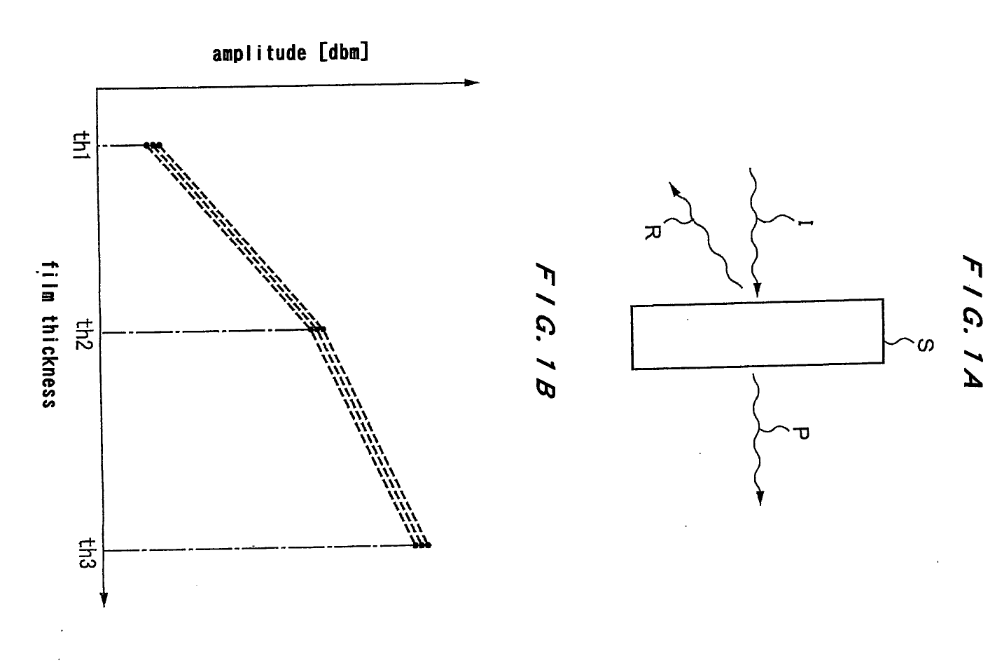

A measuring apparatus according to embodiments of the present invention will be described below with reference to the drawings. FIG. 1A is a view illustrating a principle of a measuring apparatus according to a first embodiment of the present invention. As shown in FIG. 1A, when a microwave (an incident wave I) is emitted to a substance S to be measured, the microwave is reflected by the substance S. The reflected microwave from the substance S (hereinafter referred to as a reflected wave R) has an amplitude and a phase which have varied depending on a structure such as a thickness and a physical property of the substance S. Therefore, the structure of the substance S can be analyzed by detecting at least one of the amplitude and the phase of the reflected wave R. The structure of the substance includes a thickness of the substance, an internal defect such as void formed in the substance, a dielectric constant, an electric conductivity, and a magnetic permeability.

For example, if a thickness of the substance S is changed by a polishing process, a plating process, or other processes, then the reflected wave R from the substance S varies depending on the thickness of the substance S. Accordingly, by detecting the amplitude of the reflected wave R, the change in the thickness of the substance S can be monitored. In this case, if data which indicates the relationship between the thickness of the substance S and the amplitude of the reflected wave R are stored in advance, an absolute thickness of the substance S can be measured by detecting the amplitude of the reflected wave R from the substance S.

A microwave is a kind of electromagnetic wave. In this specification hereinafter, a microwave is defined as an electromagnetic wave which has a frequency ranging from 300 MHz to 300 GHz and has a wave length ranging from 1 m to 1 mm. Information that can be read from the reflected wave R includes an amplitude and a phase thereof. Further, based on the amplitude and the phase that have been read, it is possible to obtain several kinds of information such as a reflection coefficient (i.e., a ratio of an amplitude of a reflected wave R to an amplitude of an incident wave I), a surface impedance of the substance (i.e., an impedance depending on a surface of the substance), a standing wave ratio (i.e., a ratio of a maximum voltage to a minimum voltage in a transmission line). If a frequency varies from (f) of an incident wave I to (f+Δf) of a reflected wave R, such a variation (Δf) is considered to be in proportion to a structure such as a thickness of a substance. Therefore, the structure of the substance can be analyzed by measuring the variation of the frequency.

Next, a relationship between an amplitude and a thickness of a reflected wave will be described with reference to FIG. 1B. FIG. 1B is a graph showing test results. In this test, a microwave was emitted to three types of polycrystalline silicones, which have a thickness of th1, th2 and th3 (th1<th2<th3), and an amplitude of a reflected wave was measured. In FIG. 1B, electric power (dbm) is used as unit for expressing an amplitude.

As can be seen from the test results shown in FIG. 1B, the amplitude is small when the polycrystalline silicon is thin, and the amplitude is large when the polycrystalline silicon is thick. The test results show that a constant relationship holds between the amplitude of the microwave (reflected wave) and the thickness of the substance. Therefore, the thickness of the substance can be measured by detecting the amplitude of the microwave (reflected wave).

A microwave to be emitted to the substance S is not limited to those having a single frequency. Specifically, it is possible to use several microwaves each having a different frequency, which are superimposed on one another. In addition, the frequency may be changed with time by using a frequency-varying device. It is preferable to properly choose a frequency of a microwave in accordance with a type of substance S, so that the structure of the substance S can be accurately measured. Further, because the microwave passes through the substance S, it is possible to measure the structure of the substance S by detecting not only the reflected wave R, but also a microwave which has transmitted (i.e., passed) through the substance S (hereinafter, such a microwave will be referred to as a transmitted wave P).

The followings are the advantages of the measuring apparatus using a microwave:

(1) Air is suitable medium for transmitting the microwave.

(2) The structure of the substance can be measured in a non-contact and non-destructive manner.

(3) A measurement distance can be set to be long. For example, the measurement distance of the measuring apparatus using the microwave is 35 mm, whereas that of the eddy current sensor is 4 mm at a maximum. The measurement distance is defined as a distance between an antenna (i.e., a microwave emission device) and a substance. The appropriate measurement distance is determined in consideration of a required measurement sensitivity.

(4) Even if an obstacle exists between the antenna and the substance, the microwave passes through the obstacle and can thus reach the substance. Therefore, it is not necessary to provide a transmitting window such as a through-hole in the obstacle.

(5) Generally, the antenna is small in size. Therefore, the measuring apparatus can be easily incorporated in a polishing apparatus or other apparatuses.

(6) Because the microwave can be focused onto a small region of the substance by using a focusing sensor or the like, a structure such as a thickness of the substance can be measured accurately.

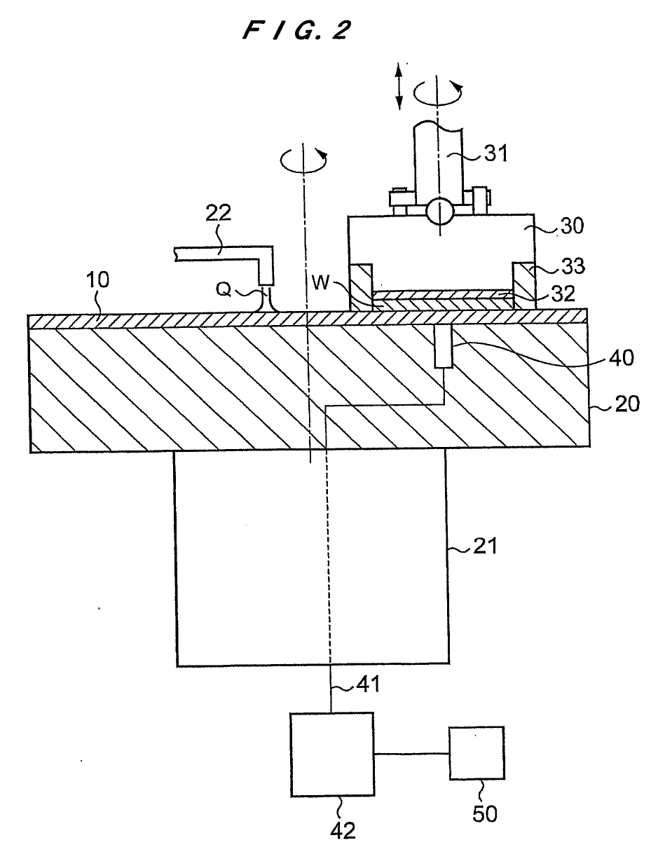

Next, a polishing apparatus (a CMP apparatus) incorporating the measuring apparatus according to the first embodiment of the present invention will be described with reference to FIG. 2. FIG. 2 is a cross-sectional view showing a polishing apparatus incorporating the measuring apparatus according to the first embodiment of the present invention.

As shown in FIG. 2, the polishing apparatus comprises a polishing table 20 having a polishing pad 10 attached on an upper surface thereof, and a top ring 30 for holding a semiconductor wafer (i.e., substrate) W, to be polished, to press the semiconductor wafer W against an upper surface of the polishing pad 10. The upper surface of the polishing pad 10 serves as a polishing surface which is brought into contact with the semiconductor wafer W as the object to be polished. An upper surface of fixed abrasive plate which comprises fine abrasive particles (made of CeO2 or the like) fixed by a binder such as resin may serve as the polishing surface.

The polishing table 20 is coupled to a motor 21 disposed therebelow, and can be rotated about its own axis as indicated by the arrow. A polishing liquid supply nozzle 22 is disposed above the polishing table 20 so that a polishing liquid Q is supplied from the polishing liquid supply nozzle 22 onto the polishing pad 10.

The top ring 30 is coupled to a motor and a lifting/lowering cylinder (not shown) through a top ring shaft 31. The top ring 30 can thus be moved vertically and rotated about the top ring shaft 31 as indicated by the arrows. An elastic mat 32 made of polyurethane or the like is attached on a lower surface of the top ring 30. The semiconductor wafer W as the object to be polished is attracted to and held by a lower surface of the elastic mat 32 by a vacuum or the like. A guide ring 33 is provided on the lower circumferential portion of the top ring 30 for thereby preventing the semiconductor wafer W from being disengaged from the top ring 30.

With the above mechanisms, the top ring 30 can press the semiconductor wafer W held on the lower surface thereof against the polishing pad 10 under a desired pressure while being rotated. In the presence of the polishing liquid Q between the semiconductor wafer W and the polishing pad 10, the lower surface of the semiconductor wafer W is polished to a flat finish.

The polishing table 20 has an antenna (a microwave emission device) 40 for emitting a microwave to the surface, to be polished, of the semiconductor wafer W. The antenna 40 is embedded in the polishing table 20. The antenna 40 is disposed at a position corresponding to a central portion of the semiconductor wafer W held by the top ring 30, and is connected to a main unit (a network analyzer) 42 through a waveguide 41.

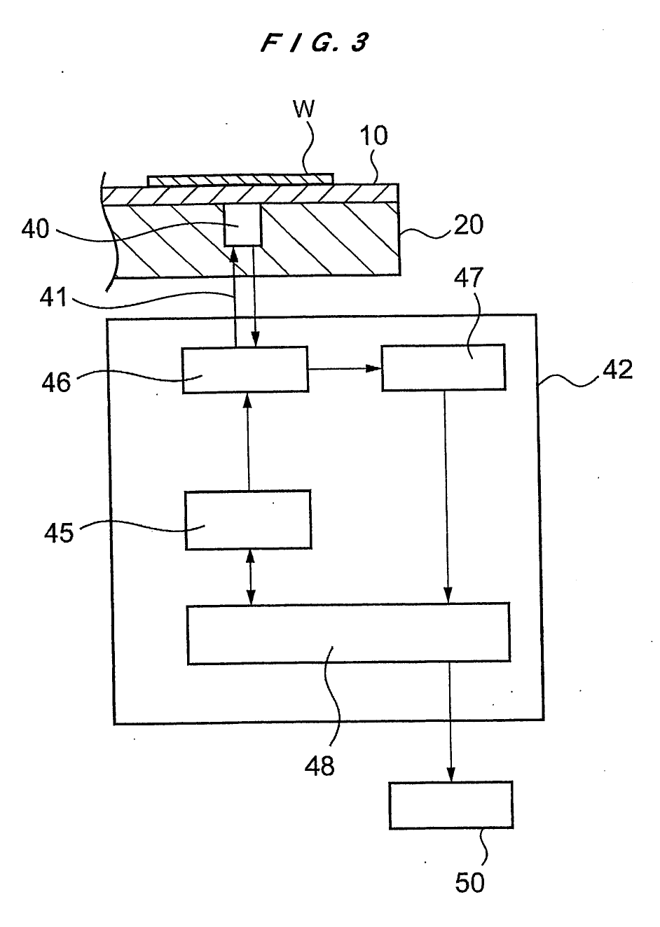

FIG. 3 is a schematic view showing the measuring apparatus according to the first embodiment of the present invention. As shown in FIG. 3, the measuring apparatus comprises the antenna 40, and the main unit 42 connected to the antenna 40 through the waveguide 41. It is preferable that a length of the waveguide 41 is as short as possible. The antenna 40 and the main unit 42 may be integrally constructed. The main unit 42 comprises a microwave source 45 for generating a microwave and supplying the generated microwave to the antenna 40, a separator 46 for separating the microwave (incident wave) generated by the microwave source 45 and the microwave (reflected wave) that has been reflected from the surface of the semiconductor wafer W from each other, a detector 47 for receiving the reflected wave which has been separated by the separator 46 and detecting an amplitude and a phase of the reflected wave, and an analyzer 48 for analyzing a structure of the semiconductor wafer W based on the amplitude and the phase of the reflected wave which have been detected by the detector 47. A directional coupler may preferably be used as the separator 46.

The antenna 40 is connected to the separator 46 through the waveguide 41. The microwave source 45 is connected to the separator 46, and the microwave generated by the microwave source 45 is supplied to the antenna 40 through the separator 46 and the waveguide 41. The microwave is emitted from the antenna 40 toward the semiconductor wafer W, and passes (penetrates) through the polishing pad 10 to reach a central portion of the semiconductor wafer W. The reflected wave from the semiconductor wafer W passes through the polishing pad 10 again and is then received by the antenna 40.

The reflected wave is sent from the antenna 40 to the separator 46 through the waveguide 41, and the incident wave and the reflected wave are separated from each other by the separator 46. The separator 46 is connected to the detector 47, and the reflected wave which has been separated by the separator 46 is sent to the detector 47. The detector 47 detects an amplitude and a phase of the reflected wave. Specifically, the amplitude of the reflected wave is measured as the value of electric power (dbm or W) or voltage (V), and the phase of the reflected wave is detected by a phase meter (not shown) incorporated in the detector 47. Only the amplitude of the reflected wave may be detected by the detector 47 without providing the phase meter, or only the phase of the reflected wave may be detected by the phase meter.

In the analyzer 48, a thickness of a metal film or a non-metal film formed on the semiconductor wafer W is analyzed based on the amplitude and the phase of the reflected wave which have been detected by the detector 47. A control unit 50 is connected to the analyzer 48. The control unit 50 detects an end point of the polishing process based on the film thickness obtained by the analyzer 48.

In order to decrease a diameter of a focal spot of the microwave, a focusing sensor for focusing the microwave may be provided on the antenna 40. With this arrangement, the microwave emitted from the antenna 40 can be applied to a small region on the semiconductor wafer W. From a viewpoint of measurement sensitivity, it is preferable that a distance (a measurement distance) between the antenna 40 and the semiconductor wafer W is as short as possible. However, the measurement distance can be set to be long while keeping the measurement sensitivity by increasing an output power of the microwave source 45.

A frequency of the microwave to be emitted to the semiconductor wafer W is preferably chosen in accordance with the kind of substance (the metal film or the non-metal film). In this case, a plurality of microwave sources may be provided for generating a plurality of microwaves each having a different frequency so that any one of the microwave sources, to be used, is chosen in accordance with the kind of substance. Alternatively, the microwave source 45 may have a frequency-varying device for varying a frequency of the microwave. In this case, the frequency-varying device may employ a function generator for varying a frequency.

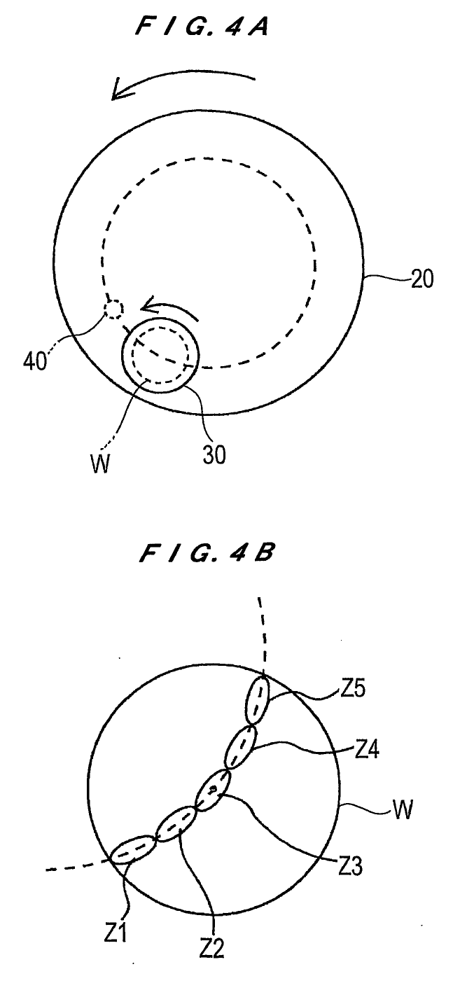

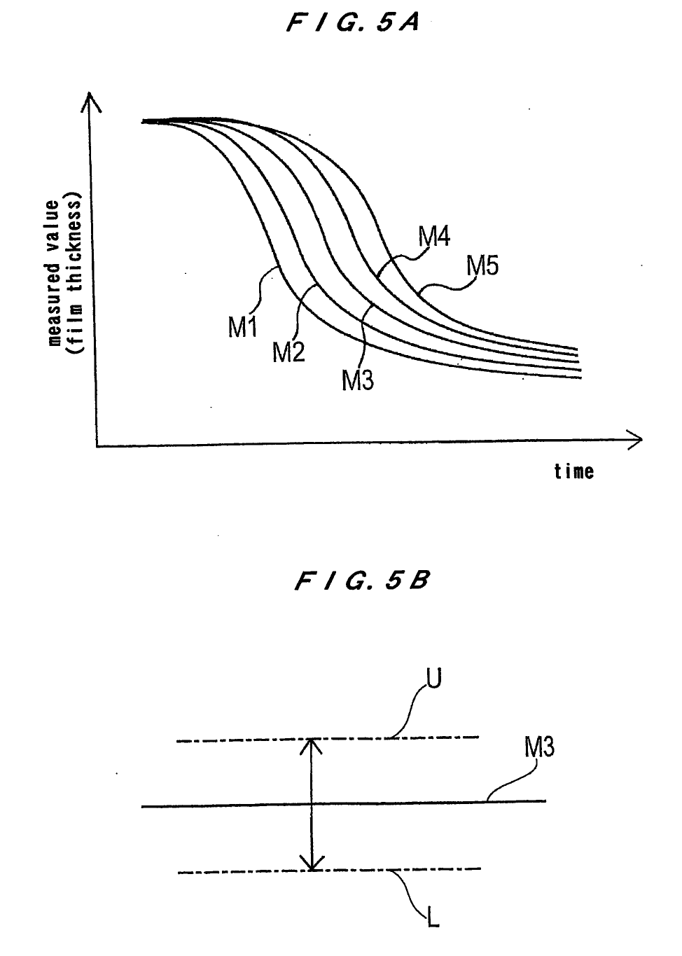

FIG. 4A is a schematic plan view showing the polishing apparatus shown in FIG. 2, and FIG. 4B is a schematic view showing a surface, to be polished, of a semiconductor wafer. FIG. 5A is a graph illustrating the manner in which measured values of film thickness at respective zones of the surface of the semiconductor wafer are changed with time, and FIG. 5B is a view illustrating a convergence range of the measured values of the film thickness.

In this embodiment, as shown in FIG. 4B, the thickness of the film is measured at five zones Z1, Z2, Z3, Z4 and Z5, one of which is positioned at the central portion of the semiconductor wafer W. As shown in FIG. 4A, the top ring 30 and the polishing table 20 are rotated independently of each other. Therefore, a position of the antenna 40 relative to the semiconductor wafer W is changed while the polishing process is performed. Even in such a situation, because the antenna 40 is disposed at a position corresponding to the central portion of the semiconductor wafer W as shown in FIG. 2, the antenna 40 sweeps across the predetermined region, i.e., the zone Z3 positioned at the central portion of the semiconductor wafer W each time the polishing table 20 makes one revolution. Therefore, it is possible to monitor the thickness of the film at a fixed region, i.e., zone Z3 that is positioned at the central portion of the semiconductor wafer W, and hence an accurate polishing rate can be obtained.

As shown in FIG. 5A, the measured values M1, M2, M3, M4 and M5 of the thickness of the film at respective zones Z1, Z2, Z3, Z4 and Z5 converge gradually within a certain range as the polishing process proceeds. As shown in FIG. 5B, in the control unit 50 (see FIGS. 2 and 3), an upper limit U and a lower limit L are provided with respect to the measured value M3 of the film thickness at zone Z3. When all of the measured values M1, M2, M3, M4 and M5 of the film thickness at zones Z1, Z2, Z3, Z4 and Z5 converge within a range from the upper limit U to the lower limit L, the control unit 50 determines that the film, to be polished, is uniformly polished over the entire surface of the semiconductor wafer W. In this manner, the polishing process is stopped when the measured values M1, M2, M3, M4 and M5 of the film thickness at the respective zones Z1, Z2, Z3, Z4 and Z5 converge within a predetermined range. Therefore, the surface can be polished to a flat finish. When the film on the semiconductor wafer W is polished to a desired thickness, the polishing process is stopped by the control unit 50.

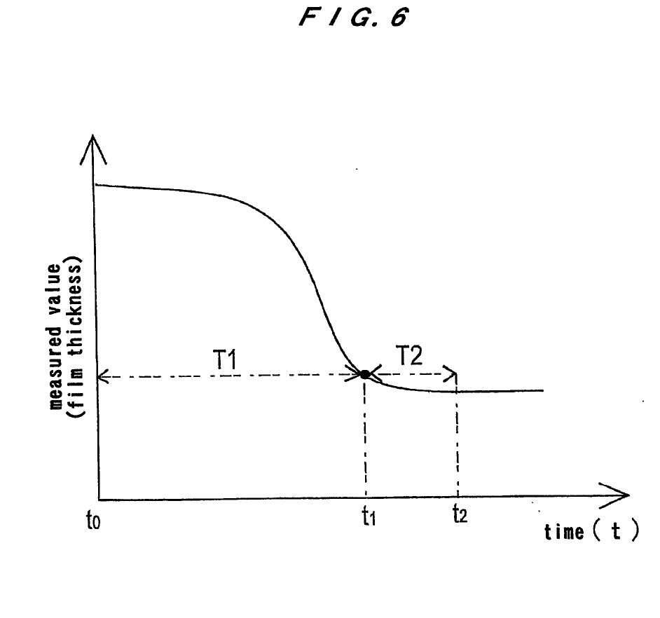

The end point of the polishing process may be detected based on an elapsed time of the polishing process. A method of detecting an end point based on the elapsed time will be described below. FIG. 6 is a graph showing the manner in which the film thickness changes with time. FIG. 6 also shows a polishing rate.

As shown in FIG. 6, when a certain time elapses since the polishing process has started (t0), rate of change in film thickness is greatly lowered. The control unit 50 (see FIGS. 2 and 3) detects such a time point (t1) and sets a base period T1 (t0−t1) Next, an auxiliary period T2 (t1−t2) is calculated by an arithmetic operation such as addition, subtraction, multiplication, and division with use of the base period T1 and a predetermined coefficient. Then, the control unit 50 stops the polishing process when a period (T1+T2), which is obtained by adding the auxiliary period T2 to the base period T1, has passed (t2).

According to this method, even if it is difficult to detect the end point of the polishing process due to a small change in the polishing rate, the end point of the polishing process can be determined by calculating the base period T1 and the auxiliary period T2. The above coefficient should preferably be determined by the kind of film such as a metal film or a non-metal film.

A temperature adjustment mechanism may be provided in the polishing table 20 so as to adjust a temperature of the polishing pad 10. For example, a fluid passage may be formed on the upper surface of the polishing table 20 so that a high-temperature fluid or a low-temperature fluid is supplied to the fluid passage. In this case, it is preferable that the control unit 50 controls the supply of the fluid based on the measured value obtained by the measuring apparatus. With this arrangement, a chemical reaction between the polishing liquid Q and the film made of metal or non-metal material is accelerated or suppressed, thus enabling the control of the polishing rate. Further, the control unit 50 may control a relative speed between the polishing table 20 and the top ring 30 based on the measured value obtained by the measuring apparatus.

It is preferable to provide a stress sensor (a frictional force detector) on the polishing table 20 for measuring a frictional force between the polishing pad 10 and the semiconductor wafer W. Alternatively, it is preferable to provide a torque sensor for measuring a torque of the top ring 30 or the polishing table 20. In this case, the torque sensor may preferably comprise a current meter for measuring current supplied to a motor which rotates the top ring 30 or the polishing table 20. In general, when the semiconductor wafer W is polished to a flat surface, the frictional force between the polishing pad 10 and the semiconductor wafer W becomes small. Therefore, if the polishing process is stopped after an output value of the stress sensor or the torque sensor is reduced to a predetermined value, then the flat surface of the semiconductor wafer W can be secured. In addition to the measuring apparatus of the present embodiment, an eddy current sensor or an optical sensor may also be provided for measuring a metal film formed on a semiconductor wafer.

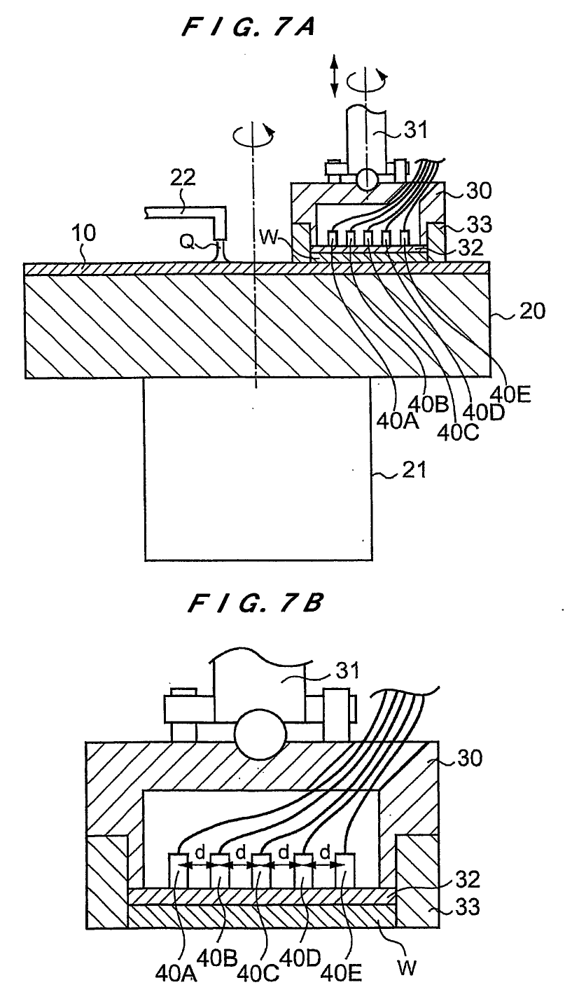

FIG. 7A is across-sectional view showing another example of the polishing apparatus incorporating the measuring apparatus according to the first embodiment of the present invention, and FIG. 7B is an enlarged cross-sectional view showing a top ring shown in FIG. 7A. The components and operations, which will not be described below, of the polishing apparatus are identical to those of the polishing apparatus shown in FIG. 2.

In the polishing apparatus shown in FIG. 7A, a plurality of antennas 40A, 40B, 40C, 40D and 40E are provided in the top ring 30, and microwaves are emitted from the respective antennas 40A, 40B, 40C, 40D and 40E toward the semiconductor wafer W. The antennas 40A, 40B, 40C, 40D and 40E are connected to the main unit 42 (see FIG. 2), respectively.

As shown in FIG. 7B, the antenna 40C is disposed at a position corresponding to the central portion of the semiconductor wafer W. The antennas 40B and 40D are disposed at positions radially apart from the antenna 40C (the central portion of the semiconductor wafer W) by a distance of “d”, respectively. The antennas 40A and 40E are disposed at positions radially apart from the antennas 40B and 40D by a distance of “d”, respectively. In this manner, the antennas 40B and 40D and the antennas 40A and 40E are arranged at different positions along the radial direction of the semiconductor wafer W.

In the polishing apparatus shown in FIG. 7A also, the thickness of the film on the semiconductor wafer W is measured at five zones Z1, Z2, Z3, Z4 and Z5 (see FIG. 4B) by the respective antennas 40A, 40B, 40C, 40D and 40E. The antennas can be provided in both the top ring 30 and the polishing table 20. In this case, a microwave is emitted toward the semiconductor wafer W from the antenna (antennas) provided in the top ring 30 or the polishing table 20, and the microwave (transmitted wave) that has been passed through the semiconductor wafer W is received by the antenna (antennas) provided at the opposite side. Then, an amplitude and a phase of the transmitted wave are detected so that the thickness of the film on the semiconductor wafer W is measured.

A location of the antenna is not limited to the polishing table 20 and the top ring 30. For example, the antenna can be provided in the guide ring 33. In this case, the measuring apparatus can be used as a sensor for detecting the disengagement of the semiconductor wafer W from the top ring 30. The antenna may be provided radially outwardly of the polishing table 20. In this case, the top ring 30 is moved to an overhanging position where a part of the top ring 30 is positioned beyond the peripheral edge of the polishing table 20 during or after the polishing process is performed, and then the microwave is emitted from the antenna to the lower surface, to be polished, of the semiconductor wafer W.

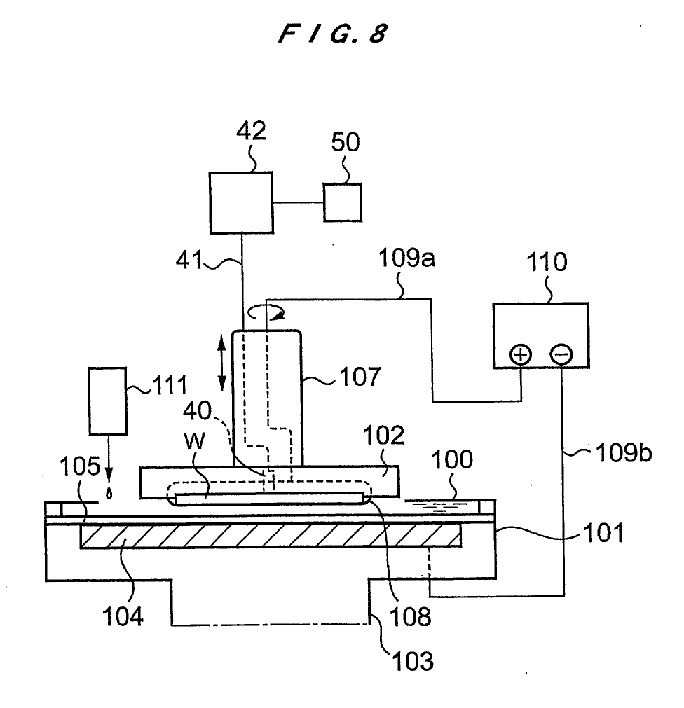

FIG. 8 is across-sectional view showing an electrolytic polishing apparatus incorporating the measuring apparatus according to the first embodiment of the present invention. As shown in FIG. 8, the electrolytic polishing apparatus comprises an electrolytic bath 101 for holding an electrolytic solution 100 therein, and a substrate holder 102 disposed above the electrolytic bath 101 for detachably holding a semiconductor wafer W in such a state that a surface to be polished faces downwardly. The electrolytic bath 101 opens upwardly and has a cylindrical shape.

The electrolytic bath 101 is coupled to a shaft 103 which is rotated by a motor (not shown). A cathode plate (i.e., a processing electrode) 104 is dipped in the electrolytic solution 100 and is placed horizontally on a bottom of the electrolytic bath 101. A polishing tool 105 of a non-woven fabric type is attached to an upper surface of the cathode plate 104. The electrolytic bath 101 and the polishing tool 105 are rotated together by the shaft 103.

The substrate holder 102 is coupled to a lower end of a support rod 107 having a rotating mechanism that can control a rotational speed and a vertical-movement mechanism that can adjust a polishing pressure. The substrate holder 102 attracts and holds the semiconductor wafer W on the lower surface thereof under a vacuum or the like.

The substrate holder 102 has an electrical contact (i.e., a feeding electrode) 108 for feeding electricity to a metal film formed on the surface of the semiconductor wafer W to make the metal film an anode. The electrical contact 108 is connected to an anode terminal of a rectifier 110 as a power source through a roll sliding connector (not shown) provided in the support rod 107 and a wire 109a. The cathode plate 104 is connected to a cathode terminal of the rectifier 110 through a wire 109b. An electrolytic solution supply 111 is disposed above the electrolytic bath 101 for supplying the electrolytic solution 100 into the electrolytic bath 101.

An antenna 40 according the present embodiment is embedded in the substrate holder 102 so that a microwave is emitted from the antenna 40 toward the semiconductor wafer W. The microwave is reflected by the metal film formed on the lower surface of the semiconductor wafer W. The reflected microwave (the reflected wave) is received by the antenna 40 and is sent to the main unit 42 through the waveguide 41. Then, a thickness of the metal film is measured by the analyzer 48 (see FIG. 3) incorporated in the main unit 42. The control unit 50 is connected to the main unit 42, and a polishing-rate control and an end-point detection of the polishing process are performed by the control unit 50 based on the value of the film thickness measured by the analyzer 48. The structure of the measuring apparatus (i.e., the antenna 40 and the main unit 42) shown in FIG. 8 is the same as that shown in FIG. 3.

Operation of the above electrolytic polishing apparatus will be described below. The electrolytic solution 100 is supplied from the electrolytic solution supply 111 into the electrolytic bath 101 until the electrolytic solution 100 overflows the electrolytic bath 101. The electrolytic bath 101 and the polishing tool 105 are rotated together while allowing the electrolytic solution 100 to overflow the electrolytic bath 101. The substrate holder 102 attracts and holds the semiconductor wafer W having the metal film such as a Cu film in such a state that the metal film faces downwardly. In this state, the semiconductor wafer W is rotated by the substrate holder 102 in the opposite direction to the rotational direction of the electrolytic bath 101. The substrate holder 102 is moved downwardly while rotating the semiconductor wafer W to bring the lower surface of the semiconductor wafer W into contact with an upper surface of the polishing tool 105 under a predetermined pressure. At the same time, direct current or pulse current is supplied between the cathode plate 104 and the electrical contact 108 from the rectifier 110. In this manner, the metal film on the semiconductor wafer W is polished to be flat. During the polishing process, the thickness of the semiconductor wafer W is measured by the measuring apparatus so that the polishing process is stopped by the control unit 50 when the metal film is polished to a desired thickness.

The electrolytic polishing apparatus shown in FIG. 8 can be used for an ultrapure water electrolytic polishing process using a catalyst. In this case, ultrapure water having an electric conductivity of 500 μg S/cm is used instead of the electrolytic solution 100, and an ion exchanger is used instead of the polishing tool 105. Operation of the ultrapure water electrolytic polishing process is the same as the above-mentioned electrolytic polishing process.

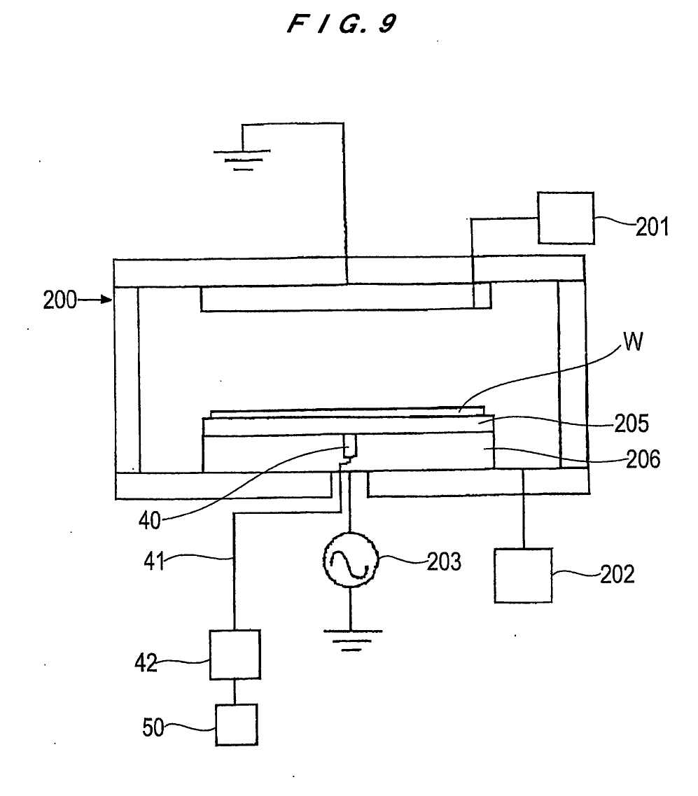

FIG. 9 is a cross-sectional view showing a dry etching apparatus incorporating the measuring apparatus according to the first embodiment of the present invention. The dry etching apparatus comprises a vacuum chamber 200, a gas supply unit 201 for supplying a predetermined gas into the vacuum chamber 200, a vacuum pump 202, and an electrode 205 connected to a high-frequency power source 203. In operation, a predetermined gas is introduced from the gas supply unit 201 into the vacuum chamber 200 while the vacuum chamber 200 is evacuated by the vacuum pump 202 as an evacuator so as to keep the interior of the vacuum chamber 200 at a predetermined pressure. Under such conditions, a high-frequency electric power is supplied from the high-frequency power source 203 to the electrode 205 to thereby generate a plasma in the vacuum chamber 200, thereby carrying out etching of a semiconductor wafer W placed on the electrode 205.

An antenna 40 according to the present embodiment is embedded in a base 206 of the electrode 205 so that a microwave is emitted from the antenna 40 toward the semiconductor wafer W. The microwave is reflected by a thin film such as a metal film or a non-metal film formed on the upper surface of the semiconductor wafer W. The reflected microwave (the reflected wave) is received by the antenna 40 and is sent to the main unit 42 through the waveguide 41. Then, a thickness of the thin film is measured by the analyzer 48 (see FIG. 3) incorporated in the main unit 42. The control unit 50 is connected to the main unit 42, and a processing-rate control and an end-point detection of the etching process are performed by the control unit 50 based on the value of the film thickness measured by the analyzer 48. The structure of the measuring apparatus (i.e., the antenna 40 and the main unit 42) shown in FIG. 9 is the same as that shown in FIG. 3. The measuring apparatus according to the present invention is applicable not only to the dry etching apparatus but also to other types of etching apparatuses such as a wet etching apparatus.

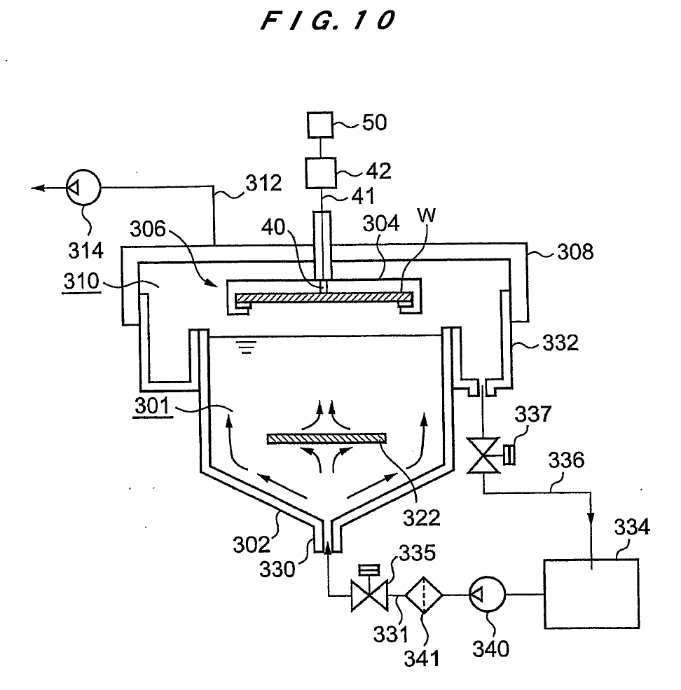

FIG. 10 is a cross-sectional view showing a plating apparatus incorporating the measuring apparatus according to the first embodiment of the present invention. As shown in FIG. 10, the plating apparatus comprises an upwardly-opened plating bath 302 having a cylindrical shape for holding a plating solution 301 therein, and a vertically-movable head section (a substrate holder) 306 having a substrate table 304 which detachably holds a semiconductor wafer W in such a state that a surface to be plated faces downwardly. A sealing cover 308 is provided to cover the upper mouth of the plating bath 302 for thereby forming a hermetic space 310 above the plating solution 301. The hermetic space 310 communicates with a vacuum pump 314 as a pressure-reducing mechanism through a discharge pipe 312 that is fixed to the sealing cover 308, so that an internal pressure of the above-mentioned hermetic space 310 is reduced by driving the vacuum pump 314.

A plate-like anode 322 is disposed horizontally and is dipped in the plating solution 301 held in the plating bath 302. A conductive layer is formed on the lower surface, to be plated, of the semiconductor wafer W, and the circumferential portion of the conductive layer is held in contact with a cathode electrode. In operation of the plating process, a predetermined voltage is applied between the anode (positive electrode) 322 and the conductive layer (negative electrode) of the semiconductor wafer W to thereby form a plated film (a metal film) on the surface of the conductive layer of the semiconductor wafer W.

The central portion of the bottom of the plating bath 302 is connected to a plating solution ejection pipe 330 as a plating solution supply unit for forming an upward flow of the plating solution 301. The plating solution ejection pipe 330 is connected to a plating solution adjustment tank 334 through a plating solution supply pipe 331. The plating solution supply pipe 331 has a control valve 335 for adjusting a valve-outlet pressure. After passing through the control valve 335, the plating solution 301 is ejected into the plating bath 302 at a predetermined flow rate from the plating solution ejection pipe 330. The upper portion of the plating bath 302 is surrounded by a plating solution receiver 332 for receiving the plating solution 301, and the plating solution receiver 332 is connected to the plating solution adjustment tank 334 through a plating solution return pipe 336. A valve 337 is provided on the plating solution return pipe 336.

The plating solution 301 that has been ejected from the plating solution ejection pipe 330 overflows the plating bath 302. The plating solution 301 that has overflowed the plating bath 302 is recovered by the plating solution receiver 332 and returned to the plating solution adjustment tank 334 through the plating solution return pipe 336. In the plating solution adjustment tank 334, a temperature of the plating solution 301 is adjusted, and concentrations of components contained in the plating solution 301 are measured and adjusted. Thereafter, the plating solution 301 is supplied from the plating solution adjustment tank 334 to the plating solution ejection pipe 330 through a filter 341 by a pump 340.

An antenna 40 according to the present embodiment is embedded in the head section (substrate holder) 306 so that a microwave is emitted from the antenna 40 toward the semiconductor wafer W. The microwave is reflected by the metal film formed on the lower surface of the semiconductor wafer W. The reflected microwave (the reflected wave) is received by the antenna 40 and is sent to the main unit 42 through the waveguide 41. Then, a thickness of the metal film is measured by the analyzer 48 (see FIG. 3) incorporated in the main unit 42. The control unit 50 is connected to the main unit 42, and a processing-rate control and an end-point detection of the plating process are performed by the control unit 50 based on the value of the film thickness measured by the analyzer 48. The structure of the measuring apparatus (i.e., the antenna 40 and the main unit 42) shown in FIG. 10 is the same as that shown in FIG. 3.

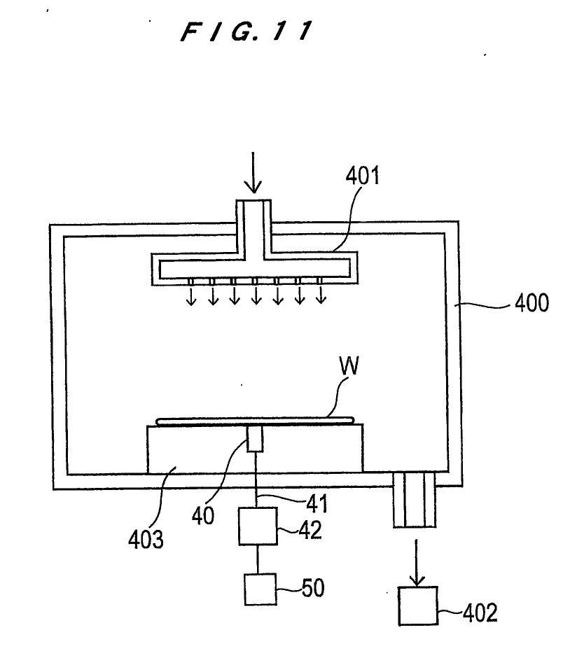

FIG. 11 is across-sectional view showing a CVD apparatus incorporating the measuring apparatus according to the first embodiment of the present invention. As shown in FIG. 11, the CVD apparatus comprises a chamber 400, a gas supply head 401 for supplying a material gas into the chamber 400, a vacuum pump 402 as an evacuator connected to the chamber 400, and a heater 403 for heating a semiconductor wafer W. The semiconductor wafer W is placed on an upper surface of the heater 403.

The material gas as a raw material for a deposit is supplied into the chamber 400 from the gas supply head 401. At the same time, the semiconductor wafer W is heated by the heater 403. Accordingly, excitation energy is applied to the material gas, and hence a product (a thin film) is deposited on the upper surface of the semiconductor wafer W. A by-product that has been produced during the deposition process of the product is evacuated from the chamber 400 by the vacuum pump 402.

An antenna 40 according to the present embodiment is embedded in the heater 403 so that a microwave is emitted from the antenna 40 toward the semiconductor wafer W. The microwave is reflected by the thin film formed on the upper surface of the semiconductor wafer W. The reflected microwave (the reflected wave) is received by the antenna 40 and is sent to the main unit 42 through the waveguide 41. Then, a thickness of the thin film deposited on the semiconductor wafer W is measured by the analyzer 48 (see FIG. 3) incorporated in the main unit 42. The control unit 50 is connected to the main unit 42, and a processing-rate control and an end-point detection of the deposition process are performed by the control unit 50 based on the value of the film thickness measured by the analyzer 48. The structure of the measuring apparatus (i.e., the antenna 40 and the main unit 42) shown in FIG. 11 is the same as that shown in FIG. 3.

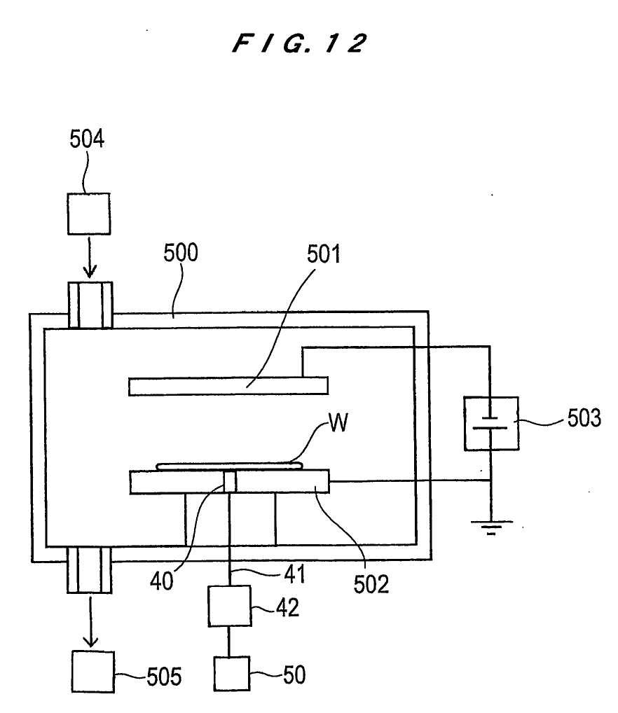

FIG. 12 is a cross-sectional view showing a PVD apparatus incorporating the measuring apparatus according to the first embodiment of the present invention. As shown in FIG. 12, the PVD apparatus (sputtering apparatus) comprises a chamber 500, a target (cathode) 501 disposed in the chamber 500, a substrate holder (anode) 502 disposed so as to face the target 501, a power source 503 for applying a voltage between the target 501 and the substrate holder 502, a gas supply unit 504 for supplying an argon gas into the chamber 500, and a vacuum pump 505 as an evacuator connected to the chamber 500. The semiconductor wafer W is placed on an upper surface of the substrate holder 502.

The chamber 500 is evacuated by the vacuum pump 505 so that a high vacuum is produced in the chamber 500. At the same time, an argon gas is supplied into the chamber 500 from the gas supply unit 504. When a voltage is applied between the target 501 and the substrate holder 502 by the power source 503, the argon gas is transformed into a plasma state due to an electric field. The argon ions are accelerated by the electric field to thereby strike the target 501. Metal atoms constituting the target 501 are sputtered by the argon ions and the sputtered metal atoms are deposited on the upper surface of the semiconductor wafer W facing the target 501, thereby forming a thin film on the upper surface of the semiconductor wafer W.

An antenna 40 according to the present embodiment is embedded in the substrate holder 502 so that a microwave is emitted from the antenna 40 toward the semiconductor wafer W. The microwave is reflected by the thin film formed on the upper surface of the semiconductor wafer W. The reflected microwave (the reflected wave) is received by the antenna 40 and is sent to the main unit 42 through the waveguide 41. Then, a thickness of the thin film deposited on the semiconductor wafer W is measured by the analyzer 48 (see FIG. 3) incorporated in the main unit 42. The control unit 50 is connected to the main unit 42, and a processing-rate control and an end-point detection of the deposition process are performed by the control unit 50 based on the value of the film thickness measured by the analyzer 48. The structure of the measuring apparatus (i.e., the antenna 40 and the main unit 42) shown in FIG. 12 is the same as that shown in FIG. 3.

Next, a measuring method and a measuring apparatus utilizing ellipsometry will be described.

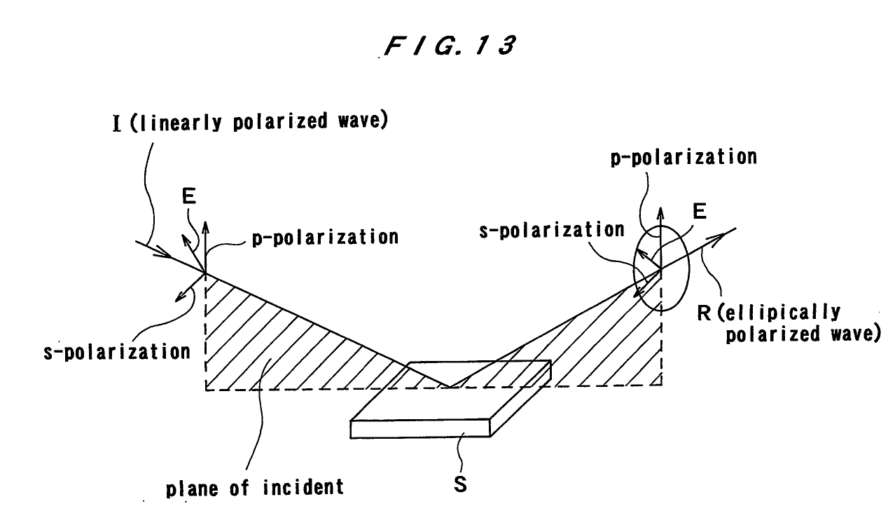

Ellipsometry is a method of measuring a thickness, a dielectric constant, a magnetic permeability, a conductivity, a refractive index, and the like of a substance by analyzing a change in polarization state of a reflected wave from the substance. A principle of the ellipsometry will be described below with reference to FIG. 13. As shown in FIG. 13, when an electromagnetic wave such as a light beam is incident obliquely onto a substance S to be measured, the electromagnetic wave is reflected by the substance S. A plane of incidence is defined as a plane containing an incident wave I and a reflected wave R. In a case where a linearly polarized wave is used as the incident wave I, an electric field vector E of the linearly polarized wave can be resolved into p-component (i.e., p-polarization) parallel to the plane of incidence and s-component (i.e., s-polarization) perpendicular to the plane of incidence. The linearly polarized wave is reflected by the substance S, and thus amplitude and phase are changed between the p-polarization and the s-polarization. As a result, the linearly polarized wave is converted into an elliptically polarized wave as shown in FIG. 13. The manner of change in amplitude and phase (i.e., change in polarization state) varies depending on the characteristic (structure) of the substance S. Therefore, a thickness, a refractive index, and the like of the substance S can be measured by analyzing the change in the polarization state.

The followings are advantages of the measuring apparatus utilizing ellipsometry:

(i) A substance to be measured may be metal or non-metal material, and hence it is not necessary to replace the measuring apparatus with another depending on the type of substance.

(ii) In a case of incorporating the above-mentioned measuring apparatus into a CMP apparatus for measuring a film thickness, it is not necessary to provide a through-hole in a polishing pad in order to allow a light beam to pass therethrough. Therefore, the measuring apparatus has no effect on a polishing process.

(iii) If an amplitude of the linearly polarized wave is modulated, then a measuring time can be minimized to, for example, 1 msec.

(iv) Because a laser is not used as a wave source, maintenance of the measuring apparatus can be facilitated.

Next, a measuring method and a measuring apparatus of a second embodiment of the present invention will be described in detail.

In this embodiment, a microwave is used as an electromagnetic wave to be emitted to a substance. Preferably, a millimeter wave having a frequency in the range of 30 to 300 GHz and a wave length in the range of 10 to 1 mm is used. Further, in order to enhance a S/N ratio and perform a quick measurement, an amplitude-modulated electromagnetic wave is preferably used. In this embodiment, the electromagnetic wave to be emitted to the substance is a linearly polarized wave or a circularly polarized wave, which is incident obliquely to the substance. In a case of using the linearly polarized wave, a direction of an electric field vector thereof is inclined at an angle of 45° in a clockwise or a counter-clockwise direction with respect to a plane perpendicular to a plane of incident.

Generally, in ellipsometry, a receive detector (i.e., a set of a receiving antenna and a detector) for receiving a reflected wave is rotated intermittently about its own axis in increment of 2° from an azimuth angle of 0° to 360° so that amplitude and phase of the reflected wave, i.e., an elliptically polarized wave, are detected at each orientation (azimuth angle). However, this method requires much time for measurement. Thus, the present embodiment employs two receive detectors which are secured in position with azimuth angles of 0° and 45°, respectively. The receive detectors have a high-polarization dependence. With this arrangement, linearly polarized components, whose vectors are directed at angles of 0° and 45°, of the elliptically polarized wave are received by the two receive detectors. After receiving the elliptically polarized wave, a ratio of a reflection coefficient of p-polarization to a reflection coefficient of s-polarization of the elliptically polarized wave is calculated in the following manner:

A reflection coefficient R_{P} of p-polarization is given by equation (1).
R_{P}=|R_{P}|·exp(j·φ_{P}) (1)

A reflection coefficient R_{S} of s-polarization is given by equation (2).
R_{S}=|R_{S}|·exp(j·φ_{S}) (2)

A ratio of the reflection coefficient R_{P} of the p-polarization to the reflection coefficient R_{S} of the s-polarization is defined by equation (3).

$$\begin{matrix}{R}_{ P} / {R}_{ S} = \vert {R}_{ P} / {R}_{ S} \vert \cdot exp ( j \cdot ( {ϕ}_{ P} - {ϕ}_{ S} ) ) \\ ≡ tan {Ψ}^{ \_} \cdot exp ( jΔ )\end{matrix} \\ tan \overline{Ψ} \text{:} amplitude ratio \\ Δ \text{:} phase difference \qquad ( 3 )$$

In this manner, the ratio of the reflection coefficient R_{P} of the p-polarization to the reflection coefficient R_{S} of the s-polarization can be expressed by Ψ (psi) and Δ (delta). Ψ and Δ are determined by an incident angle, a thickness of the substance to be measured, and the like. Therefore, a thickness, a dielectric constant, a magnetic permeability, a conductivity, a refractive index, and the like of the substance can be measured based on the values of Ψ and Δ by inverse estimation.

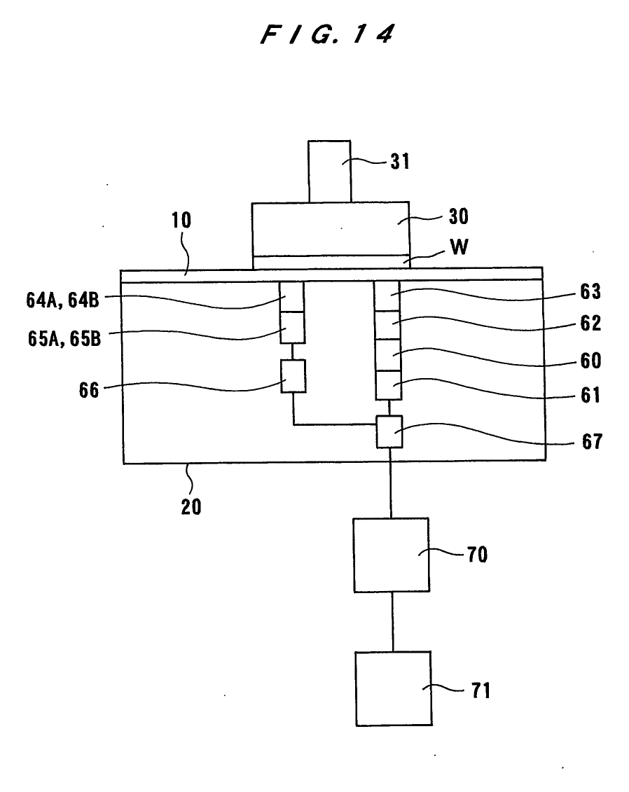

Next, a measuring apparatus according to the second embodiment will be described with reference to FIG. 14. FIG. 14 is a schematic view showing a measuring apparatus according to the second embodiment of the present invention. This embodiment shows an example in which the measuring apparatus is incorporated in a CMP apparatus. Components and operations, which will not be described below, of the CMP apparatus of this embodiment are identical to those of the polishing apparatus shown in FIG. 2.

As shown in FIG. 14, the measuring apparatus comprises a millimeter wave source 60, an amplitude modulator 61 for modulating an amplitude of the millimeter wave, a polarizer 62 for converting the millimeter wave into a linearly polarized wave, a transmitting antenna (an emission device) 63 for emitting the linearly polarized wave onto a semiconductor wafer W, two receiving antennas 64A and 64B for receiving an elliptically polarized wave reflected by the semiconductor wafer W, two detectors 65A and 65B connected respectively to the receiving antennas 64A and 64B, a preamplifier 66 for amplifying signals sent from the detectors 65A and 65B, a lock-in amplifier 67 for detecting predetermined signals from the signals with noise, a rotary joint 70, and a analyzer 71 for measuring a thickness and the like of the semiconductor wafer W by analyzing the detected signals.

The transmitting antenna 63 is provided in a polishing table 20, and disposed at a position close to a central portion of the semiconductor wafer W held by a top ring 30. The linearly polarized wave (i.e., the millimeter wave) is emitted in an oblique direction from the transmitting antenna 63 toward a central portion of the semiconductor wafer W on the polishing pad 10. The linearly polarized wave is obliquely incident onto the polishing pad 10 and passes through the polishing pad 10 to reach the central portion of the semiconductor wafer W. The objects (substances) to be measured are the polishing pad 10 and a multilayered film comprising laminated thin films formed on a lower surface of the semiconductor wafer W. Examples of the thin films to be measured include an insulating film of SiO2 or Poly-Si, a metal film of Cu or W (tungsten), a barrier film of Ti, TiN, Ta, or TaN.

The millimeter wave source 60 may comprise a Gunn oscillator, or a combination of a Gunn oscillator and a multiplier. Alternatively, a combination of a microwave oscillator and a multiplier may be used as the millimeter wave source 60. The polarizer 62 may comprise a waveguide having a polarization dependence. In order to enhance a directivity of the linearly polarized wave to be emitted to the semiconductor wafer W, a pyramidal horn antenna may preferably be used for the transmitting antenna 63. In a case of using a circularly polarized wave instead of the linearly polarized wave, conical horn antennas are used for the receiving antennas 64A and 64B. The detectors 65A and 65B may comprise a Schottky barrier beam read diode, or a combination of a mixer and a Schottky barrier beam read diode.

The millimeter wave to be emitted to the semiconductor wafer W is the linearly polarized wave. If X-axis (not shown) is defined as a direction perpendicular to a plane of incident containing an incident wave and a reflected wave, an electric field vector of the linearly polarized wave is inclined at an angle of 45° in a clockwise or a counter-clockwise direction with respect to the X-axis in a plane perpendicular to a propagating direction. A circularly polarized wave may be used as the millimeter wave to be emitted to the semiconductor wafer W. In this case, a circular polarizer is used instead of the above-mentioned polarizer 62.

The linearly polarized wave is obliquely emitted to the semiconductor wafer W from the single transmitting antenna 63, and then reflected by the surface and each interface of the multilayered thin films, which are objects of measurement. The reflected wave from the semiconductor wafer W is received by the two receiving antennas 64A and 64B. These two receiving antennas 64A and 64B are inclined at azimuth angles of 0° and 45° with respect to the X-axis, respectively, so that linearly polarized components of the elliptically polarized wave are detected at azimuth angles of 0° and 45° by the two detectors 65A and 65B. With this structure having the two receiving antennas 64A and 64B and the two detectors 65A and 65B, a ratio Ψ of an amplitude of p-polarization to an amplitude of s-polarization and a phase difference Δ between the p-polarization and the s-polarization are simultaneously detected during a polishing process. The detected signals are sent to the analyzer 71 vie the preamplifier 66, the lock-in amplifier 67, and the rotary joint 70. The analyzer 71 calculates the thickness of the film on the semiconductor wafer W based on the values of Ψ and Δ with use of, for example, a Newton method. A control unit 50 (see FIG. 2) detects an end point of the polishing process with use of index which is correlated with the film thickness.

In this manner, decrease of the polishing pad 10 and decrease of the thin films such as an oxide film and a metal film formed on the semiconductor wafer W can be measured by simultaneously detecting the ratio Ψ of the amplitude of the p-polarization to the amplitude of the s-polarization and the phase difference Δ between the p-polarization and the s-polarization. Further, an accuracy in detecting the both parameters Ψ and Δ can be improved by using the two receiving antennas 64A and 64B which are secured in position. Four receiving antennas may be used in such a manner that the four receiving antennas are inclined respectively at azimuth angles of 90°, 45°, 0° and −45°. In this case also, four detectors are connected to four receiving antennas, respectively. With this arrangement having four receiving antennas and four detectors, common mode components including common mode noise can be rejected due to differential detection, and hence a S/N ratio is improved. Further, a differential output may be divided by sum signal so that fluctuation of intensity of the electromagnetic wave and fluctuation of reflectance of the semiconductor wafer W are cancelled.

As described above, by analyzing the change in polarization state of the reflected wave from the substance to be measured, an amount of change in thickness of the polishing pad 10 due to dressing (conditioning), an amount of change in thickness of an oxide film as a dielectric and an amount of change in thickness of a metal film can be measured during the polishing process. In this embodiment, the polishing pad 10 is one of the objects to be measured. Since the polishing pad 10 is typically made of urethane foam, the millimeter wave can be transmitted through the polishing pad 10. Therefore, it is possible to measure thickness of multilayered thin films beyond the polishing pad 10. The measuring apparatus of this embodiment can measure a thickness of several types of films such as an insulating film of SiO2 or Poly-Si, a metal film of Cu or W (tungsten), a barrier film of Ti, TiN, Ta, or TaN. For example, in a case of using a millimeter wave having a frequency of 100 GHz, it is possible to measure a thickness of a Cu film as long as its thickness is not more than 225 nm, which is given by the following formula:

$$δ = \sqrt{\frac{2}{ω μ σ}} = \sqrt{\frac{2}{2 π ( 100 ⨯ {10}^{9} ) ( 4 π ⨯ {10}^{- 7} ) ( 5 ⨯ {10}^{7} )}} ≅ 225 nm$$

$$f = 100 GHz , \\ σ = 5 ⨯ {10}^{7} S / m ( @ Cu )$$

μ: magnetic permeability σ: conductivity

A conventional optical measuring apparatus can measure a thickness of a Cu film as long as its thickness is not more than 30 nm. However, as a semiconductor fabricating process proceeds, a thickness of a whole multilayered film is increased. Thus, in order to control the polishing process, it is required to measure a thickness of such a multilayered film even when its thickness becomes large. In this regard, the measuring apparatus of this embodiment has an advantage over the conventional optical measuring apparatus.

The measuring apparatus according to the present invention is applicable not only to a polishing apparatus, but also to a plating apparatus, a CVD apparatus, a PVD apparatus, and the like for forming or depositing a thin film such as a metal film or a non-metal film on a surface of a semiconductor wafer.

According to the present invention, a structure of a substance can be measured by using an unprecedented new technique. Particularly, it is possible to measure a metal film such as Cu, Al, Au and W, an under-barrier film such as SiOC, a barrier film such as Ta, TaN, Ti, TiN and WN, an oxide film such as SiO2, a polycrystalline silicon, BPSG (boro phospho silicate glass) film, a TEOS (tetra ethoxy silane) film, and the like, which are formed on a semiconductor wafer. Further, because an end point of a polishing process can be detected accurately while performing a polishing process (in-situ), the total number of processing steps can be reduced, compared to a conventional measuring method in which a film thickness is measured after the polishing process is stopped (ex-situ). Furthermore, in operation of a CMP apparatus for polishing a substrate having a film such as a shallow trench isolation (STI), an interlayer dielectric (ILD or IMD), Cu, or W, and also in operation of a plating apparatus and a CVD apparatus for forming these films, it is possible to detect an end point of any types of processes performed by the above apparatuses.

As described above, according to the present invention, even if an obstacle (e.g., a polishing pad) is disposed between a substance as an object to be measured and an emission device, a microwave passes (penetrates) through the obstacle to reach the substance (e.g., a substrate). Therefore, it is not necessary to provide a transmitting window such as a through-hole in the obstacle. As a result, a process for providing such a transmitting window is not required, and hence the fabrication cost can be reduced. Further, according to the present invention, a thickness or the like of the substance can be measured accurately without being affected by a polishing liquid or the like.

### INDUSTRIAL APPLICABILITY

The present invention is applicable to a measuring apparatus for measuring a thickness or the like of a substance such as a thin film formed on a surface of a semiconductor wafer.

1. A measuring apparatus comprising:
a microwave emission device for emitting a microwave to a substance;
a microwave generator for supplying the microwave to said microwave emission device;
a detector for detecting an amplitude or a phase of the microwave which has been reflected from or passed through the substance; and
an analyzer for analyzing a structure of the substance based on the amplitude or the phase of the microwave which has been detected by said detector.

2. A measuring apparatus according to claim 1, wherein said analyzer calculates at least one of a reflection coefficient, a standing wave ratio, and a surface impedance.

3. A measuring apparatus according to claim 1, wherein said analyzer measures at least one of a thickness, an internal defect, a dielectric constant, an electric conductivity, and a magnetic permeability of the substance.

4. A polishing apparatus for polishing a substrate by bringing the substrate into sliding contact with a polishing pad, said polishing apparatus comprising:
a polishing table having said polishing pad;
a top ring for holding the substrate and pressing the substrate against said polishing pad; and
a measuring apparatus for measuring a thickness of a film formed on a surface of the substrate;
wherein said measuring apparatus comprises a microwave emission device for emitting a microwave to the film, a microwave generator for supplying the microwave to said microwave emission device, a detector for detecting an amplitude or a phase of the microwave which has been reflected from or passed through the film, and an analyzer for measuring a thickness of the film based on the amplitude or the phase of the microwave which has been detected by said detector.

5. A polishing apparatus according to claim 4, wherein:
a plurality of said microwave emission devices are provided in said top ring;
one of said plurality of said microwave emission devices is disposed at a position corresponding to a central portion of the substrate; and
the others of said plurality of said microwave emission devices are disposed apart from the central portion of the substrate in a radial direction of the substrate.

6. A polishing apparatus according to claim 4, further comprising at least one of an eddy current sensor, an optical sensor, a frictional force detector for detecting a frictional force between said polishing pad and the substrate, and a torque sensor for detecting a torque of said top ring or said polishing table.

7. A CVD apparatus for forming a film on a surface of a substrate, said CVD apparatus comprising:
a chamber in which the substrate is disposed;
a gas supply for supplying a material gas into said chamber;
a heater for heating the substrate; and
a measuring apparatus for measuring a thickness of the film formed on the surface of the substrate;
wherein said measuring apparatus comprises a microwave emission device for emitting a microwave to the film, a microwave generator for supplying the microwave to said microwave emission device, a detector for detecting an amplitude or a phase of the microwave which has been reflected from or passed through the film, and an analyzer for measuring a thickness of the film based on the amplitude or the phase of the microwave which has been detected by said detector.

8. A measuring apparatus comprising:
an emission device for emitting a linearly polarized wave or a circularly polarized wave to a substance;
at least two receive devices each for receiving a reflected wave from the substance;
at least two detectors each for detecting an amplitude and a phase of the reflected wave; and
an analyzer for analyzing a change in polarization state of the reflected wave based on the amplitude and the phase which have been detected by said detectors so as to measure a thickness of the substance.

9. A measuring apparatus according to claim 8, wherein said analyzer further measures a dielectric constant, an electric conductivity, a magnetic permeability, and a refractive index of the substance.

10. A measuring apparatus according to claim 8, wherein the substance is a multilayered film.

11. A polishing apparatus for polishing a substrate by bringing the substrate into sliding contact with a polishing pad, said polishing apparatus comprising:
a polishing table having said polishing pad;
a top ring for holding the substrate and pressing the substrate against said polishing pad; and
a measuring apparatus for measuring a thickness of a substance formed on a surface of the substrate;
wherein said measuring apparatus comprises an emission device for emitting a linearly polarized wave or a circularly polarized wave to the substance, at least two receive devices each for receiving a reflected wave from the substance, at least two detectors each for detecting an amplitude and a phase of the reflected wave, and an analyzer for analyzing a change in polarization state of the reflected wave based on the amplitude and the phase which have been detected by said detectors so as to measure a thickness of the substance.

12. A polishing apparatus according to claim 11, wherein said emission device is disposed in said polishing table.

13. A polishing apparatus according to claim 11, wherein the substance is a multilayered film.
